(19) United States
(12) Patent Application Publication
(10) Pub. No.: US 2006/0132182 A1
(43) Pub. Date: Jun. 22, 2006

(54) Driver circuit, shift register, and liquid crystal driver circuit

(75) Inventor: Koji Kikuchi, Miyagi-ken (JP)

Correspondence Address: BEYER WEAVER & THOMAS LLP, P.O. BOX 70250, OAKLAND, CA, 94612-0250, US

(73) Assignee: ALPS ELECTRIC CO., LTD.

(21) Appl. No.: 11/289,829

(22) Filed: Nov. 29, 2005

(30) Foreign Application Priority Data
Dec. 22, 2004 (JP) 2004-371012

(51) Int. Cl. H03K 19/094

(52) U.S. Cl. 326/83

(57) ABSTRACT

A driver circuit according to the present invention includes a transistor for outputting a voltage input from a drain as an output signal from a source, a first capacitor disposed between a gate and the source of the output transistor to increase an application voltage applied to the gate, and an adjustment circuit for adjusting a voltage value of the application voltage.

### BACKGROUND OF THE INVENTION

1. Field of the Invention

The present invention relates to, for example, a shift register provided in a liquid crystal display unit such as a liquid crystal display to supply a scan driving signal, and to a liquid crystal driver circuit using such a shift register.

2. Description of the Related Art

In an active matrix liquid crystal display unit used as a display unit, for example, in a computer or a mobile phone, video signal lines (column wires) and scan driving signal lines (row wires) are arranged in a matrix. At each of the intersections of these wires is provided a switching element, such as a thin film transistor, that drives liquid crystal for a pixel.

In such an active matrix liquid crystal display unit, a scan driving signal is supplied to a plurality of scan driving signal lines to sequentially scan these signal lines, so that all switching elements on one scan driving signal line are temporarily made conductive (turned ON) at a time. On the other hand, a video signal is supplied to the video signal lines in synchronization with the scan driving signal lines.

A shift register is used to sequentially supply the scan driving signal to the plurality of scan driving signal lines.

Referring to FIG. 10, a plurality of row wires and a plurality of column wires are arranged in a matrix in a display section. A liquid crystal element including a switching element (transistor) that controls the application of voltage to liquid crystal and a controlled liquid crystal section is arranged at each of the intersections of these row wires and column wires to form an active matrix circuit.

A gate driver (shift register) time-sequentially applies a predetermined voltage to the row wires (scanning lines) to turn them ON. When a driver for the column wires applies a predetermined voltage (via the signal lines) to sources in synchronization with this timing, the optical state of liquid crystal is changed to drive the liquid crystal display unit.

In order to drive the liquid crystal elements, the gate driver shown in FIG. 10 is formed of a thin film transistor (see, for example, Japanese Unexamined Patent Application Publication No. 08-87897).

The gate driver that applies voltage to the row wires needs to be operated at high speed to supply sufficient current to the row wires.

Referring to FIG. 11, the gate driver includes a shift register composed of a plurality of shift register (SR) stages.

Each SR stage is constructed as shown in FIG. 12. A plurality of the SR stages is cascade-connected as shown in FIG. 11 to function as the gate driver. More specifically, the SR stages sequentially apply voltage as a drive pulse from respective output terminals OUT (OUTn−1, OUTn, OUTn+1, and OUTn+2) to the column wires in response to clocks C (C1, C2, and C3), thus applying a predetermined voltage to the gate of the thin film transistor in each liquid crystal element.

Referring to FIG. 13 which is a waveform diagram depicting driving waveforms, the shift register is designed so that a gate voltage Vgs (gate-to-source voltage) that turns an output transistor 16 sufficiently ON (sufficiently low ON resistance) is applied to a node P1 shown in FIG. 12 before and after the output of the drive pulse (phase shift clock).

As is apparent from FIG. 12, the voltage at the node P1 becomes higher than the input voltage (in fact, a value obtained by dividing the threshold value of the transistor) due to a bootstrap effect resulting from an increase in the voltage at a node 13 with the clock C1. For this reason, the HIGH voltage of the output voltage from the output OUTn can be increased to the HIGH voltage of the clock C1.

A thin film transistor (TFT) formed of amorphous silicon (a-Si) is used as the above-described transistor. In this a-Si TFT, a threshold voltage shifts from factory-set Vth to Vth′, as shown in FIG. 14, due to a stress corresponding to a voltage applied to the gate, causing the output current to decrease from Ion to Ion′. This situation gradually degrades the function as a switch over time, and finally the transistor in the display section cannot be sufficiently driven.

In short, since a drive voltage itself applied to the gate electrode in the a-Si TFT is stress, the value of this drive voltage greatly affects the length of the operating life. More specifically, the higher the drive voltage, the shorter the operating life.

On the other hand, sufficient electric current cannot flow and therefore fast driving of the transistor in the display section cannot be achieved without a predetermined voltage being applied to the gate of the a-Si TFT.

### SUMMARY OF THE INVENTION

The present invention has been conceived in light of these circumstances, and it is an object to provide a driver circuit, a shift register, or a liquid crystal driver circuit using such a shift register that increase the operating speed of a transistor in a display section and allow the operating life for an a-Si TFT for driving this transistor to become longer than before.

A driver circuit according to one aspect of the present invention includes a transistor for outputting a voltage input from a drain as an output signal from a source; a first capacitor disposed between a gate and the source of the output transistor to increase an application voltage applied to the gate; and an adjustment circuit for adjusting a voltage value of the application voltage.

With the above-described structure, the driver circuit according to the present invention allows the voltage applied to the transistor to be adjusted to a predetermined voltage required for an output destination (e.g., a minimum voltage required to switch at a predetermined rate transistors that drive display elements in a display section of a liquid crystal display unit). As a result, application of a voltage more than necessary can be avoided, which advantageously suppresses the amount of shift in threshold voltage Vth. This extends the service life of the transistor, namely, the circuit operation.

The above-described driver circuit may further include an input transistor for transmitting an input signal input to a drain to a source. In this driver circuit, the source of the input transistor may be connected to the gate of the output transistor, and the adjustment circuit may include a second capacitor disposed between the drain of the input transistor and the gate of the output transistor.

In the above-described driver circuit, the adjustment circuit may include a second capacitor disposed between the gate and a ground wire.

With this structure, the driver circuit according to the present invention can have the adjustment circuit as a voltage-dividing circuit with a simple structure. A voltage increased by the first capacitor can easily be adjusted to a predetermined voltage to be applied to the gate voltage of the transistor through the capacitance ratio between the first capacitor and the second capacitor.

In the above-described driver circuit, the capacitance ratio between the first capacitor and the second capacitor is a value for adjusting the application voltage to a voltage which causes the voltage input from the drain to be substantially equal to a voltage of the output signal.

In the driver circuit, according to the present invention, with the above-described structure, the gate voltage of the transistor is applied to a voltage corresponding to the threshold voltage Vth of the transistor according to the capacitance ratio between the first capacitor and the second capacitor. Since a voltage corresponding to the voltage input from the drain is output from the source, sufficiently high voltage and current that drive a transistor, i.e., the next stage, of the display section can be output and application of unnecessarily high voltages can be avoided. This minimizes stresses applied to the transistor.

A shift register according to another aspect of the present invention includes a plurality of stages connected to one another in a row to perform a shift operation of an output signal by shifting input data using a plurality of clocks with different phases and outputting a clock input to a drain of an output transistor as a phase shift clock from a source upon the input data being input. In the shift register, one of the above-described driver circuits is used for the output transistor.

In the above-described shift register, an (n−1)-th phase shift clock is input as shift data to an n-th stage to increase a gate voltage of the output transistor by a capacitor disposed between the source and the gate by using an n-th phase shift clock output from the source of the transistor.

With this structure, the shift register according to the present invention employs a driver that allows the above-described operating life to be longer than that in a known example. This can extend the operating life of the circuit itself.

A liquid crystal driver circuit according to still another aspect of the present invention includes the above-described shift register to generate a scan driving signal for an active matrix circuit composed of scanning lines and signal lines intersecting with one another.

With this structure, the liquid crystal driver circuit according to the present invention employs a shift register that allows the above-described operating life to be longer than that in a known example. This can extend the operating life of the circuit itself.

As described above, according to the present invention, an application voltage to be applied to the gate of the driving transistor in the driver circuit can be adjusted to a voltage value with which a substantially minimum voltage and current required for the circuit of the next stage can be supplied. As a result, stresses applied to the transistor can be decreased compared with in a known circuit by using an application voltage required for operation with necessary driving capabilities.

### BRIEF DESCRIPTION OF THE DRAWINGS

FIG. 1 is a block diagram depicting an exemplary structure of a shift register according to first and second embodiments of the present invention;

FIG. 2 is a schematic diagram depicting an exemplary structure of a circuit of a stage in FIG. 1 (stage 2 in the description) according to the first embodiment;

FIG. 3 is a waveform diagram illustrating an exemplary operation of a shift register according to the first embodiment (or the second embodiment);

FIGS. 4A to 4C are schematic diagrams depicting a change in the amount of electric charge in the capacitors Ca and Cb shown in FIG. 2;

FIG. 5 is a graph illustrating the amount of shift in threshold value of a transistor over time depending on a voltage applied to the gate;

FIG. 6 is a schematic diagram depicting a circuit structure of a modification of FIG. 2;

FIG. 7 is a schematic diagram depicting an exemplary structure of a circuit of a stage in FIG. 1 (stage 2 in the description) according to the second embodiment;

FIGS. 8A to 8C are schematic diagrams depicting a change in the amount of electric charge in the capacitors Ca and Cb shown in FIG. 7;

FIG. 9 is a schematic diagram depicting a circuit structure of a modification of FIG. 7;

FIG. 10 is a schematic diagram depicting the structure of a liquid crystal display unit;

FIG. 11 is a block diagram depicting the structure of a shift register according to a known example;

FIG. 12 is a schematic diagram depicting a circuit structure of each stage shown in FIG. 11;

FIG. 13 is a waveform diagram depicting an exemplary operation of the shift register shown in FIG. 10; and

FIG. 14 is a graph depicting the correspondence between Vgs (gate-to-source voltage) and Ids (drain current) of an FET.

### DESCRIPTION OF THE PREFERRED EMBODIMENTS

The present invention relates to a technology for controlling a shift in threshold voltage of an output transistor to prolong the operating life of a shift register that uses a driver circuit (an output circuit including an output transistor M1 to be described later) compared with a structure in which a voltage increased in a known manner is applied to a gate as-is. This is achieved with an adjustment circuit provided in a register cell, which corresponds to each stage of a shift register formed of, for example, an a-Si on a substrate of a liquid crystal display unit, so as to adjust the gate voltage of the output transistor outputting a phase shift clock Gout, which is a scan driving signal that drives a liquid crystal element, from an increased voltage to a voltage required by the circuit in the next stage.

A more specific description of this technology is as follows. In each stage of the shift register according to the present invention, the output transistor (M1) in the n-th stage n is turned ON by the voltage of the phase shift clock Gout (n−1) which outputs from the “n−1”-th stage n−1 the voltage of a clock to be input to the drain of an output transistor (M1) in the n-th stage n, and a first capacitor provided between the gate and the source increases the gate voltage by the voltage output to the source.

In the stage, a second capacitor is interposed between a terminal of the first capacitor (i.e., the terminal connected to the gate) and the grounding voltage to divide the voltage according to the capacitance ratio between the first capacitor and the second capacitor, thus adjusting the increased voltage applied to the gate to a gate voltage that supplies voltage and current required for the next stage.

### First Embodiment

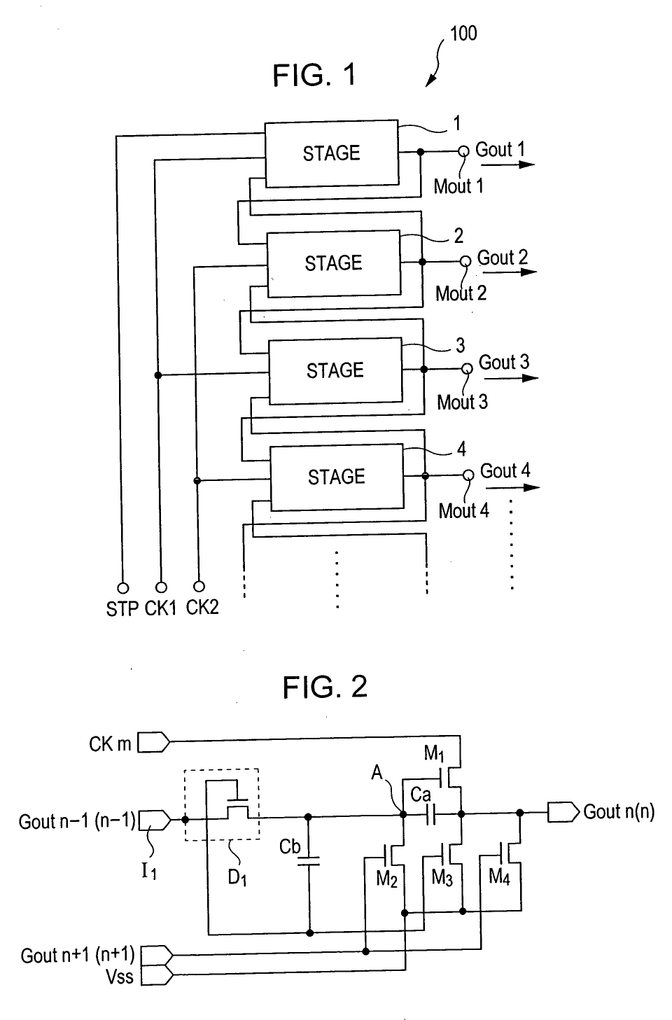

A shift register used in a gate driver (component of a liquid crystal driver circuit) in the liquid crystal display unit shown in FIG. 10 according to a first embodiment of the present invention will now be described with reference to the drawings. FIG. 1 is a block diagram depicting an exemplary structure of a shift register according to the first embodiment.

Referring to FIG. 1, a shift register 100 includes a plurality of stages (register cells) 1, 2, 3, 4, and so on connected to one another in a row. Input data (pulse of a start signal STP) is shifted by clocks with a plurality of phases, for example, clocks with two phases (CK1 and CK2) input from an external clock generator to achieve synchronization with a clock with the phase input to this stage in the stage to which the input data is input. In this manner, the phase shift clocks Gout1, Gout2, Gout3, Gout4, and so on are sequentially output from the stages to terminals Mout1, Mout2, Mout3, Mout4, and so on, respectively.

While one of the two-phase clocks is being input to each stage in order of phase, a stage outputs output data (a phase shift clock) in synchronization with the input clock when the sequentially shifted input data reaches itself.

In the example of FIG. 1, the stage 1 outputs the phase shift clock Gout1, the stage 2 outputs the phase shift clock Gout2, the stage 3 outputs the phase shift clock Gout3, and the stage 4 outputs the phase shift clock Gout4.

More specifically, in the shift register 100, the input data input by the start signal STP is sequentially shifted by the two-phase clocks. Then, a stage to which the input data is input outputs a phase shift clock to the liquid crystal element as a driving signal via the connected terminal Moutn in synchronization with the clock input to this stage.

The clock CK1 is input to the stage 1, the clock CK2 is input to the stage 2, the clock CK1 is input to the stage 3, the clock CK2 is input to the stage 4, and so on. Thus, the clock CKm is input to the stage n, where m represents a remainder obtained by dividing n by “2” (n is 2 if the remainder is 0).

The structure of the stage 2 of the shift register shown in FIG. 1 will now be described with reference to FIG. 2. FIG. 2 is a schematic diagram depicting a circuit structure of the stage 2 (other stages have the same structures as that of this stage 2, though different signals are input).

In FIG. 2, the Moutn corresponds to the Mout2, the “n−1”-th stage n−1 corresponds to the stage 1, the “n+1”-th stage n+1 corresponds to the stage 3, and the clock CKm corresponds to the clock CK2.

In an output transistor M1, the drain of a transistor M2 is connected to the gate, the clock CK2 is input to the drain, and the source is connected to the terminal Mout2.

In the transistor M2, the source is connected to the ground, the drain is connected to the gate of the output transistor M1, and the gate is connected to the output terminal Mout(n+1) of the next stage, i.e., the “n+1”-th stage n+1. In other words, the phase shift clock Gout3, which is the output of the next stage 3, is input to the gate.

A diode D1 is an input circuit for inputting the phase shift clock Gout1 (Goutn−1). The anode is connected to a terminal I1 and the cathode is connected to the gate of the output transistor M1 (connected via a node A).

This diode D1 may be formed of a transistor, as shown in FIG. 2. In this case, a terminal formed by connecting the gate and the drain is used as the anode and the source is used as the cathode.

In a capacitor Ca, one terminal is connected to the cathode of the diode D1, and the other terminal is connected to the source of the output transistor M1. In short, the capacitor Ca is interposed between the cathode of the diode D1 and the source of the output transistor M1.

In a capacitor Cb, one terminal is connected to the cathode of the diode D1, and the other terminal is connected to the anode of the diode D1. In short, the capacitor Cb is connected in series with the capacitor Ca between the source of the output transistor M1 and the anode of the diode D1.

With this structure, the nodes of the capacitor Ca and the capacitor Cb are connected to the gate of the output transistor M1.

In a transistor M3, the source is connected to the ground, the drain is connected to the source of the output transistor M1, and the gate is connected to the output terminal Mout(n−1) of the previous stage, i.e., the “n−1”-th stage n−1, so that the phase shift clock Gout1 is input as a control signal.

In a transistor M4, the source is connected to the ground, the drain is connected to the source of the output transistor M1, and the gate is connected to the output terminal Mout(n+1) of the next stage, i.e., the “n+1”-th stage n+1. In other words, the phase shift clock Gout3, which is the output of the next stage 3, is input to the gate.

The output transistor M1 and the transistors M2, M3, and M4 are all n-channel FETs (field effect transistors).

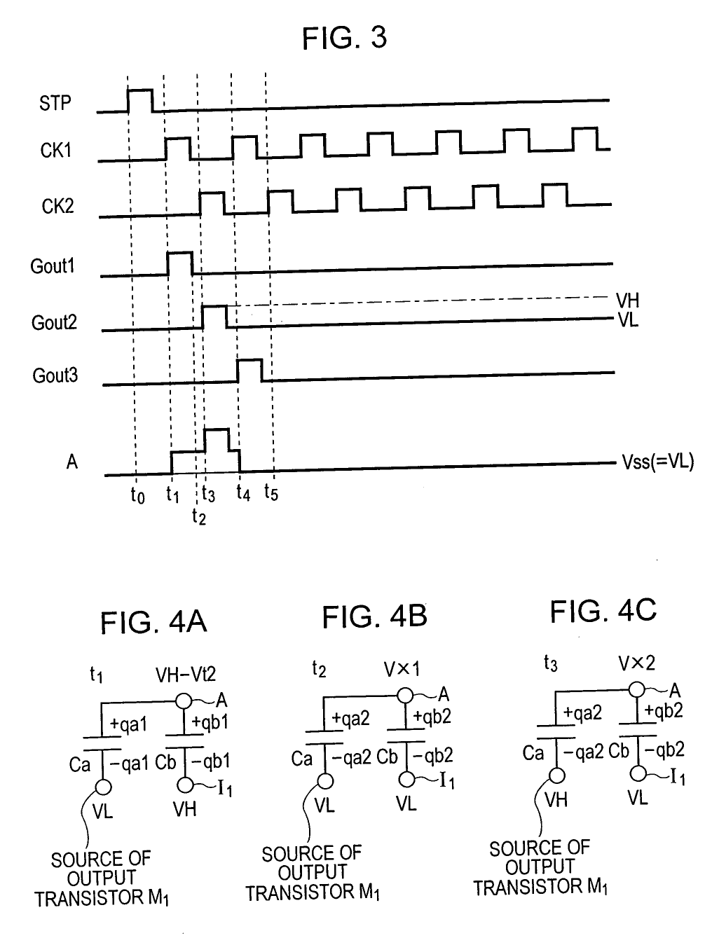

The operation of the shift register according to the first embodiment of the present invention will now be described with respect to the stage 2 by referring to FIG. 3. FIG. 3 is a waveform diagram illustrating the operation of the stage 2 of the shift register according to the first embodiment.

In the stage 2, the clock CK2 is input to the drain of the output transistor M1, the anode (input terminal I1) of the diode D1 is connected to the output terminal Mout1 of the previous stage 1, and the gates of the transistors M2 and M4 are connected to the output terminal Mout3 of the next stage 3.

At time t0, the start signal STP is input, and the start signal STP having a voltage value and a pulse width similar to those of the clocks CK1 and CK2 (output from the clock generator with substantially the same timings as the temporal relationship of the clock CK2 with the clock CK1) is input to the stage 1.

Next, at time t1, the clock CK1 is input to the stage 1, and the stage 1 (the output transistor M1 of the stage 1) outputs the phase shift clock Gout1 from the output terminal Mout1 with the start signal STP as an output shifted from the clock CK1.

At this time, the phase shift clock Gout1 is input to the anode of the diode D1 of the stage 2. Since the transistor M3 is ON, the output terminal Mout2 goes the “L” level, and the phase shift clock Gout3 is at the “L” level, the transistors M2 and M4 are OFF. Accordingly, the voltage value at the point A is from the voltage value (crest value VH of the pulse) of the phase shift clock Gout1 to the forward voltage (value obtained by subtracting the threshold value Vt2 of the transistor) of the diode D1, and the output transistor M1 is turned ON.

At this time, as shown in FIG. 4A, electric charge for generating potential Vg1 (VH) obtained by subtracting the forward voltage (threshold value Vt2 of the transistor) of the diode D1 from the voltage value (crest value of the pulse) of the phase shift clock Gout1 is accumulated between both ends of the capacitor Ca.

Here, the above-described potential Vg1, when observed in terms of the amount of electric charge accumulated in the capacitor Ca and capacitor Cb, is represented as shown in Expression (1).
qa1=Ca·{(VH−Vt2)−VL}=Ca(VH−VL−Vt2)
qb1=Cb·{(VH−Vt2)−VH}=−Cb·Vt2 (1)

In Expression (1), qa1 represents the amount of electric charge accumulated in the capacitor Ca and qb1 represents the amount of electric charge accumulated in the capacitor Cb.

VH represents the crest value (the highest voltage value of the pulse), VL represents the bottom value (the lowest voltage value of the pulse), Ca represents the capacitance value of the capacitor Ca, Cb represents the capacitance value of the capacitor Cb, and Vt2 represents the threshold voltage of the transistor constituting the diode D1.

However, since the transistor M3 is ON and the drain of the output transistor M1 is at the “L” level without input of the clock CK2, the output transistor M1 does not output the phase shift clock Gout2.

Next, at time t2, the clock CK1 shifts from the “H” level to the “L” level, and the terminal of the capacitor Cb connected to the anode of the diode D1 goes the “L” level as shown in FIG. 4B. As a result, the amount of electric charge accumulated in the capacitors Ca and Cb changes as shown in Expression (2) below.
qa2=Ca·(Vx1−VL)
qb2=Cb·(Vx1−VL) (2)

Therefore, equation (+qa1)+(+qb1)=(+qa2)+(+qb2) holds for the potential Vx1 at the point A based on the charge conservation law.

Consequently, equation Ca·(VH−VL−Vt2)−Cb·Vt2=Ca·(Vx1−VL)+Cb·(Vx1−VL) is established.

Therefore, the potential Vx1 at the point A is obtained from Expression (3) below.
Vx1={Ca·(VH−Vt2)−Cb·(Vt2−VL)}/(Ca+Cb) (3)

The potential Vg1 generated at time t1 is divided based on the capacitance ratio between the capacitors Ca and Cb at time t2.

Next, at time t3, the clock CK2 is input from the clock generator to the second stage 2 as a pulse with the same voltage value and width as those of the clock CK1.

At this time, since the phase shift clock Gout1 goes the “L” level and the gate of the transistor M3 goes the “L” level, the transistor M3 is turned OFF. Since the phase shift clock Gout3 is still at the “L” level, the transistors M2 and M4 are OFF.

This causes the clock CK2 to be input to the drain of the output transistor M1. Since the output transistor M1 is already ON, a voltage Vg2 obtained by subtracting the threshold value of the output transistor M1 from the voltage value (crest value VH) of the clock CK2 input to the drain is output from the source.

Therefore, the voltage value at the source of the output transistor M1 changes from the “L” level to VH−Vt1 (threshold value of the output transistor M1). Consequently, it increases to VH as the gate voltage increases, as described below.

In other words, the voltage value Vx1 at the point A is increased by the source voltage of this output transistor M1 and the gate voltage of the output transistor M1 increases. It is eventually output from the source of the output transistor M1 as a phase shift clock Gout2 with the same voltage as the crest value VH of the clock CK1, as shown in FIG. 4C.

The voltage applied to the gate of the output transistor M1 at this time, namely, the voltage at the point A is VG2. The capacitance ratio between the capacitor C1 and capacitor C2 is set so that this voltage Vg2 is substantially near VH+Vt1.

Here, the amount of electric charge accumulated in the output transistor capacitors Ca and Cb is given by Expression (4) from the potential Vx2 at the above-described point A.
qa3=Ca·(Vx2−VH)
qb3=Cb·(Vx2−VL) (4)

From the amount of electric charge in each capacitance at time t1 based on Expression (1) and from Expression (4), equation (+qa1)+(+qb1)=(+qa3)+(+qb3) holds based on the charge conservation law.

Consequently, equation Ca·(VH−VL−Vt2)−Cb·Vt2=Ca·(Vx2−VH)+Cb·(Vx2−VL) is established.

Therefore, the potential Vx2 at the point A is obtained from Expression (5) below.
Vx2={Ca·(2·VH−VL−Vt2)−Cb·(Vt2−VL)}/(Ca+Cb) (5)

At time t3, the potential generated due to an increase in the voltage at the point A resulting from an increase in the voltage at the source of the output transistor M1 is divided based on the capacitance ratio between the capacitor Ca and capacitor Cb.

Therefore, voltage and electric current required for the next stage can be supplied and a shift in threshold voltage of the output transistor M1 can be suppressed by setting the capacitance ratio between the capacitors Ca and Cb in the design so that the voltage at the point A, namely, the voltage Vx2 applied to the gate of the output transistor M1 is a value similar to VH+Vt1 or, if possible, a value lager than VH+Vt1 by a small amount of compensation.

This causes the phase shift clock Gout2 with VH to be output from the source of the output transistor M1 at time t3.

Next, at time t4, the clock CK2 input to the drain of the output transistor M1 changes from VH to VL, and the clock CK1 changes from VL to VH. As a result of the phase shift clock Gout3 with an “H” level being output from the next stage 3, an “H”-level voltage is applied to the gates of the transistor M2 and the transistor M4 to cause the transistors M2 and M4 to become ON. Consequently, the output terminal Mout2 changes from the “H” level to the “L” level.

As described above, according to the first embodiment of the present invention, a phase shift clock G with a voltage value similar to those of the clocks CK1 and clock CK2 can be output.

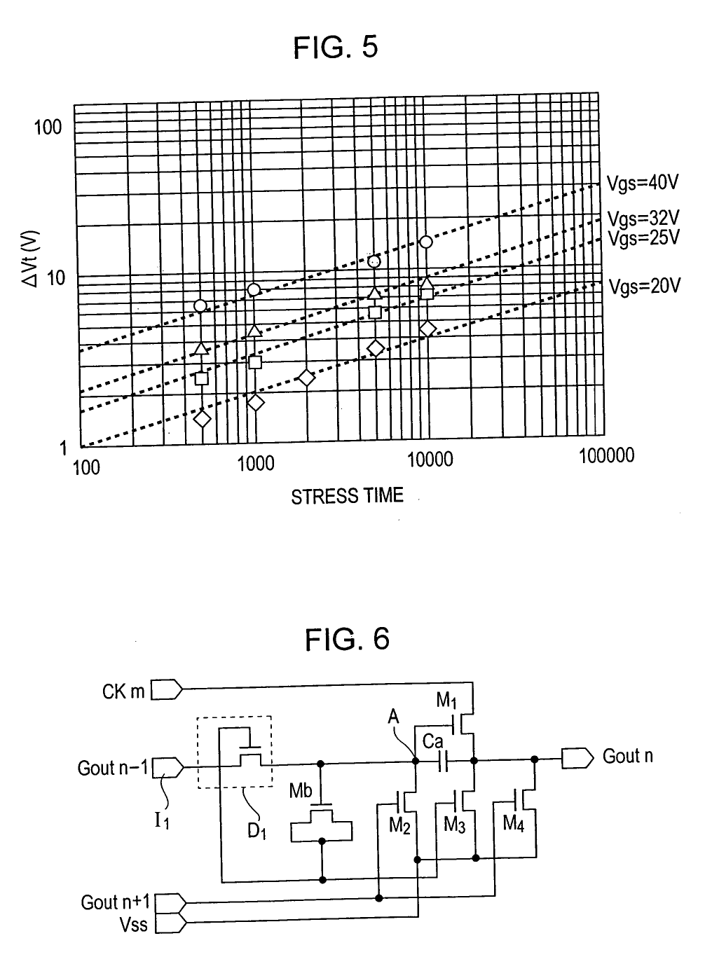

For example, the experimental data in FIG. 5 (vertical axis representing the amount of change ΔVt in threshold value and horizontal axis representing a stress application time) shows that as the voltage Vgs (gate-to-source voltage) to be applied to the gate decreases, the amount of change ΔVt in the threshold value decreases.

For example, if VH is 17 V and VL is 0 V, a voltage of 25 V is applied to the gate of the output transistor M1 at time t3 for a known buffer which does not have a circuit for adjusting the voltage applied to the gate according to the present invention.

On the other hand, for a buffer provided with a voltage-adjusting circuit according to the present invention, the capacitors Ca and Cb are set so that the threshold voltage Vt1 of the output transistor M1 is 2 V, the compensation value is 1 V, and Vx2 is 20 V.

By doing this, it is apparent from the experimental data in FIG. 5 that the time required for ΔVt to change by 3 V in the case of 20 V is approximately four to six times longer than in the case of 25 V. Considering that the service life of the transistor depends on a shift in the threshold value, the service life of the output transistor M1, namely, the service life of the shift register including this output transistor M1 can be prolonged by the use of the circuit according to the present invention.

FIG. 6 shows an example where the capacitor Cb according to the first embodiment shown in FIG. 2 is realized by a transistor Mb. The operation is the same as that described in the first embodiment.

### Second Embodiment

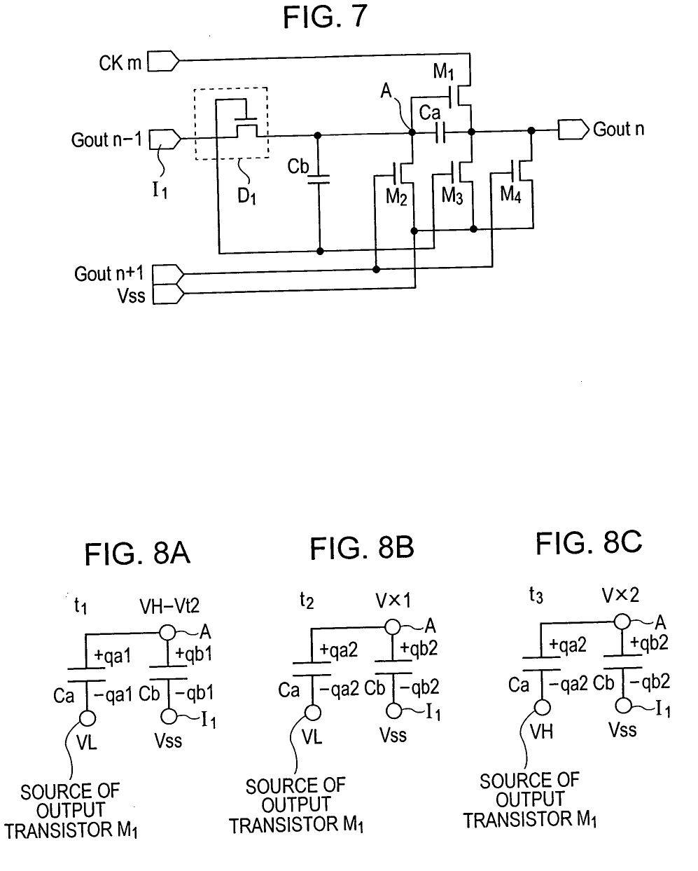

A shift register according to a second embodiment of the present invention will now be described with reference to FIG. 7. FIG. 7 is a schematic diagram depicting a circuit structure of one stage in a shift register (same as that in FIG. 1) according to the present invention (other stages have the same structures as that of this stage 2, though different signals are input).

The second embodiment differs from the first embodiment in that one terminal of the capacitor Cb in the second embodiment is connected to the gate of the output transistor M1 and the other terminal of the capacitor Cb is connected to the ground.

Furthermore, except for the above-described points, the circuit according to the second embodiment has the same structure and operation as the circuit according to the first embodiment shown in FIG. 2.

The operation of the shift register according to the second embodiment of the present invention will now be described with respect to the stage 2 by referring to FIG. 3. FIG. 3 is a waveform diagram depicting the operation of the stage 2 in the shift register according to the second embodiment.

In the stage 2, the clock CK2 is input to the drain of the output transistor M1, the anode (input terminal I1) of the diode D1 is connected to the output terminal Mout1 in the previous stage 1, and the gates of the transistors M2 and M4 are connected to the output terminal Mout3 in the next stage “stage 3”.

At time t0, the start signal STP is input, and the start signal STP having a voltage value and a pulse width similar to those of the clocks CK1 and CK2 (output from the clock generator with substantially the same timings as the temporal relationship of the clock CK2 with the clock CK1) is input to the stage 1.

Next, at time t1, the clock CK1 is input to the stage 1, and the stage 1 (the output transistor M1 of the stage 1) outputs the phase shift clock Gout1 from the output terminal Mout1 with the start signal STP as an output shifted from the clock CK1.

At this time, the phase shift clock Gout1 is input to the anode of the diode D1 of the stage 2. Since the transistor M3 is ON, the output terminal Mout2 goes the “L” level, and the phase shift clock Gout3 is at the “L” level, the transistors M2 and M4 are OFF. Accordingly, the voltage value at the point A is from the voltage value (crest value VH of the pulse) of the phase shift clock Gout1 to the forward voltage (value obtained by subtracting the threshold value Vt2 of the transistor) of the diode D1, and the output transistor M1 is turned ON.

At this time, as shown in FIG. 8A, electric charge for generating a potential Vg1 (VH) obtained by subtracting the forward voltage (threshold value Vt2 of the transistor) of the diode D1 from the voltage value (crest value of the pulse) of the phase shift clock Gout1 is accumulated between both ends of the capacitor Ca.

Here, the above-described potential Vg1, when observed in terms of the amount of electric charge accumulated in the capacitor Ca and capacitor Cb, is represented as shown in Expression (6).
qa1=Ca·{(VH−Vt2)−VL}=Ca·(VH−VL−Vt2)
qb1=Cb·{(VH−Vt2)−Vss}=Cb·(VH−Vss−Vt2) (6)

In Expression (6), qa1 represents the amount of electric charge accumulated in the capacitor Ca and qb1 represents the amount of electric charge accumulated in the capacitor Cb.

VH represents the crest value (the highest voltage value of the pulse), VL represents the bottom value (the lowest voltage value of the pulse), Ca represents the capacitance value of the capacitor Ca, Cb represents the capacitance value of the capacitor Cb, and Vt2 represents the threshold voltage of the transistor constituting the diode D1.

However, since the transistor M3 is ON and the drain of the output transistor M1 is at the “L” level without input of the clock CK2, the output transistor M1 does not output the phase shift clock Gout2.

Next, at time t2, the clock CK2 shifts from the “H” level to the “L” level, and the terminal of the capacitor Cb connected to the anode of the diode D1 goes the “L” level as shown in FIG. 8B. As a result, the amount of electric charge accumulated in the capacitors Ca and Cb changes as shown in Expression (7) below.
qa2=Ca·(Vx1−VL)
qb2=Cb·(Vx1−Vss) (7)

Therefore, equation (+qa1)+(+qb1)=(+qa2)+(+qb2) holds for the potential Vx1 at the point A based on the charge conservation law.

Consequently, equation Ca·(VH−VL−Vt2)+Cb·(VH−Vss−Vt2)=Ca·(Vx1−VL)+Cb·(Vx1−Vss) is established.

Therefore, the potential Vx1 at the point A is obtained from Expression (8) below.
Vx1={Ca·(VH−Vt2)−Cb·(Vt2−VL)}/(Ca+Cb)=VH−Vt2 (8)

The potential Vg1 generated at time t1 is divided based on the capacitance ratio between the capacitors Ca and Cb at time t2.

Next, at time t3, the clock CK2 is input from the clock generator to the second stage 2 as a pulse with the same voltage value and width as those of the clock CK1.

At this time, since the phase shift clock Gout1 goes the “L” level and the gate of the transistor M3 goes the “L” level, the transistor M3 is turned OFF. Since the phase shift clock Gout3 is still at the “L” level, the transistors M2 and M4 are OFF.

This causes the clock CK2 to be input to the drain of the output transistor M1. Since the output transistor M1 is already ON, a voltage Vg2 obtained by subtracting the threshold value of the output transistor M1 from the voltage value (crest value VH) of the clock CK2 input to the drain is output from the source.

Therefore, the voltage value at the source of the output transistor M1 changes from the “L” level to VH−Vt1 (threshold value of the output transistor M1). Consequently, it increases to VH as the gate voltage increases, as described below.

In other words, the voltage value Vx1 at the point A is increased by the source voltage of this output transistor M1 and the gate voltage of the output transistor M1 increases. It is eventually output from the source of the output transistor M1 as a phase shift clock Gout2 with the same voltage as the crest value VH of the clock CK1, as shown in FIG. 8C.

The voltage applied to the gate of the output transistor Ml at this time, namely, the voltage at the point A is VG2. The capacitance ratio between the capacitor C1 and capacitor C2 is set so that this voltage Vg2 is substantially near VH+Vt1.

Here, the amount of electric charge accumulated in the output transistor capacitors Ca and Cb is given by Expression (9) from the potential Vx2 at the above-described point A.
qa3=Ca·(Vx2−VH)
qb3=Cb·(Vx2−VssL) (9)

From the amount of electric charge in each capacitance at time t1 based on Expression (6) and from Expression (9), equation (+qa1)+(+qb1)=(+qa3)+(+qb3) holds based on the charge conservation law.

Consequently, equation Ca·(VH−VL−Vt2)+Cb·(VH−Vss−Vt2)=Ca·(Vx2−VH)+Cb·(Vx2−Vss) is established.

Therefore, the potential Vx1 at the point A is obtained from Expression (10) below.
Vx2={Ca·(2·VH−VL−Vt2)+Cb·(VH−Vt2)}/(Ca+Cb) (10)

At time t3, the potential generated due to an increase in the voltage at the point A resulting from an increase in the voltage at the source of the output transistor M1 is divided based on the capacitance ratio between the capacitor Ca and capacitor Cb.

Therefore, in the same manner as in the first embodiment, voltage and electric current required for the next stage can be supplied and a shift in threshold voltage of the output transistor M1 can be suppressed by setting the capacitance ratio between the capacitors Ca and Cb in the design so that the voltage at the point A, namely, the voltage Vx2 applied to the gate of the output transistor M1 is a value similar to VH+Vt1 or, if possible, a value lager than VH+Vt1 by a small amount of compensation.

This causes the phase shift clock Gout2 with VH to be output from the source of the output transistor M1 at time t3.

Next, at time t4, the clock CK2 input to the drain of the output transistor M1 changes from VH to VL, and the clock CK1 changes from VL to VH. As a result of the phase shift clock Gout3 with an “H” level being output from the next stage 3, an “H”-level voltage is applied to the gates of the transistor M2 and the transistor M4 to cause the transistors M2 and M4 to be turned ON. Consequently, the output terminal Mout2 changes from the “H” level to the “L” level.

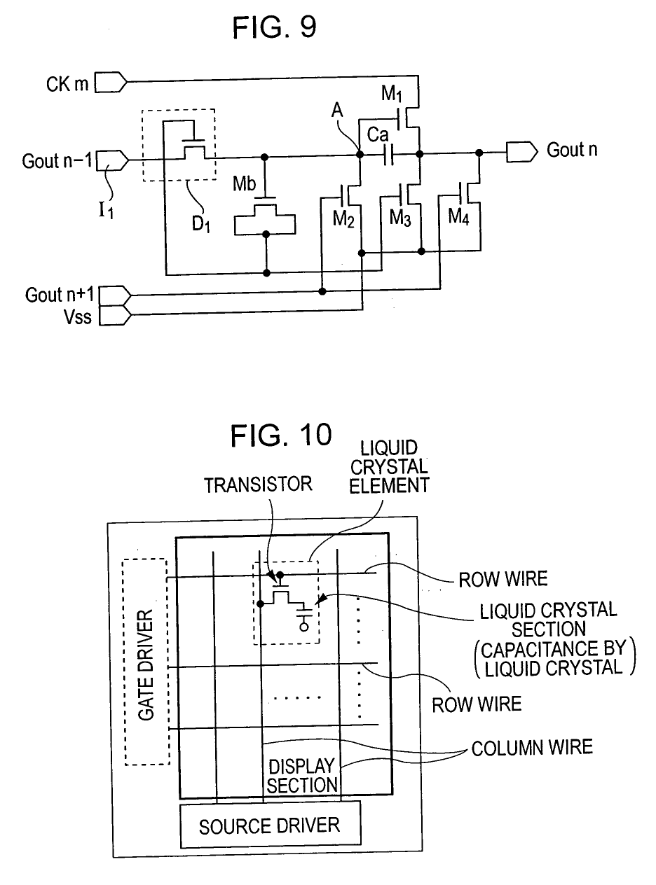

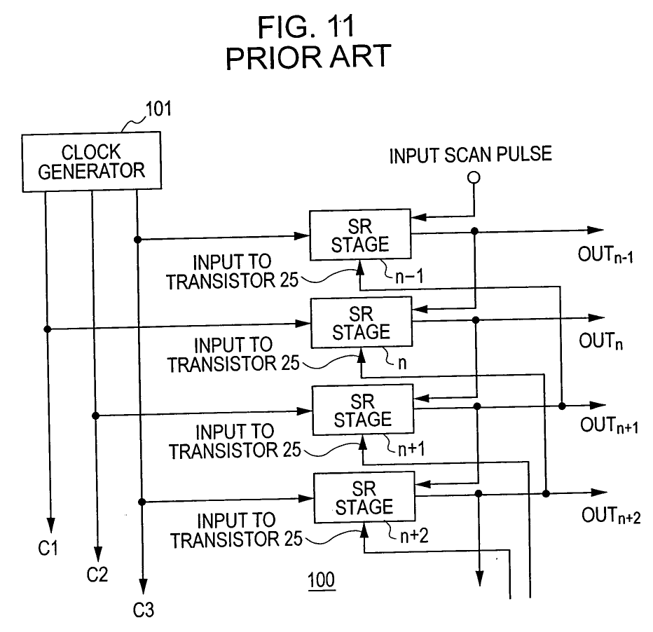

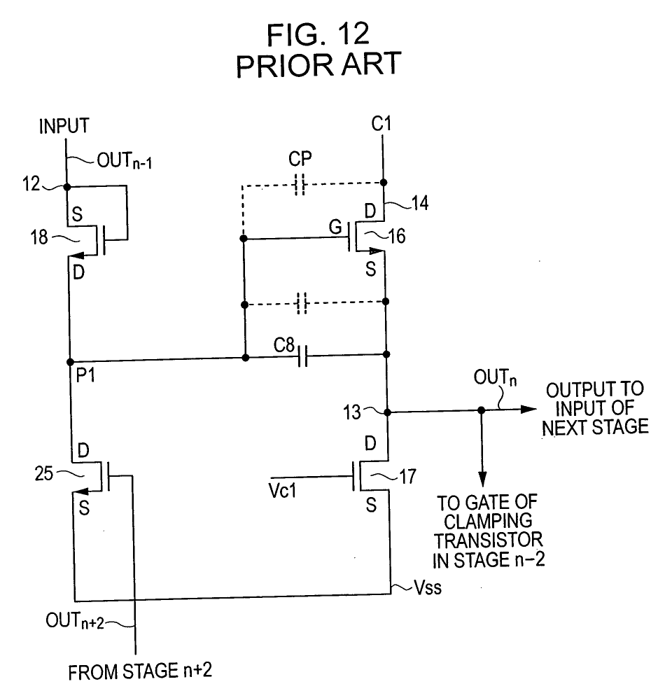

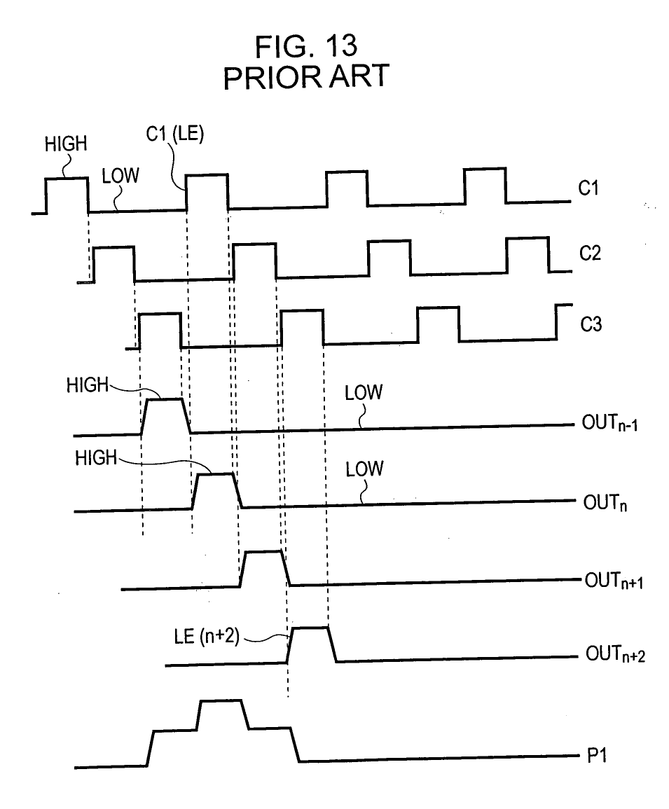

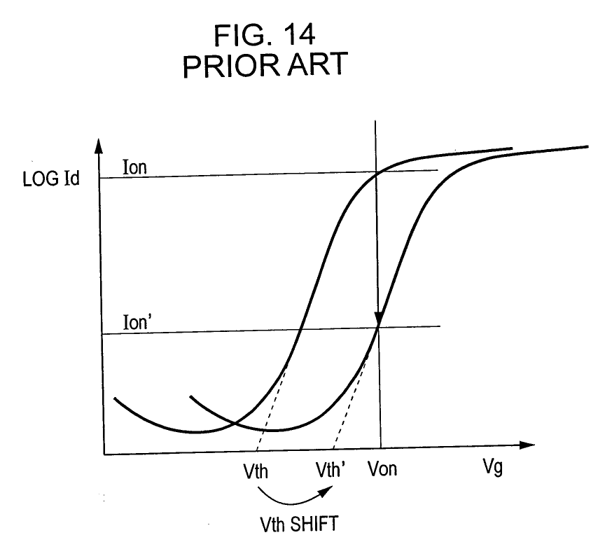

Furthermore, in the above-described circuit structure of FIG. 7, the capacitor Cb can be replaced with a transistor Mb as shown in FIG. 9.

In addition, the operating life of the driver circuit of the liquid crystal display unit, namely, the liquid crystal display unit can be extended by employing a shift register having a driver circuit according to the first or second embodiment of the present invention for the liquid crystal driver circuit (gate driver) that drives the transistors of the liquid crystal elements in the display section of the liquid crystal display unit shown in FIG. 10.

What is claimed is:

1. A driver circuit comprising:
a transistor for outputting a voltage input from a drain as an output signal from a source;
a first capacitor disposed between a gate and the source of the output transistor to increase an application voltage applied to the gate; and
an adjustment circuit for adjusting a voltage value of the application voltage.

2. The driver circuit according to claim 1, further comprising:
an input transistor for transmitting an input signal input to a drain to a source, wherein
the source of the input transistor is connected to the gate of the output transistor, and wherein
the adjustment circuit includes a second capacitor disposed between the drain of the input transistor and the gate of the output transistor.

3. The driver circuit according to claim 1, wherein the adjustment circuit includes a second capacitor disposed between the gate and a ground wire.

4. The driver circuit according to claim 2, wherein a capacitance ratio between the first capacitor and the second capacitor is a value for adjusting the application voltage to a voltage which causes the voltage input from the drain to be substantially equal to a voltage of the output signal.

5. The driver circuit according to claim 3, wherein a capacitance ratio between the first capacitor and the second capacitor is a value for adjusting the application voltage to a voltage which causes the voltage input from the drain to be substantially equal to a voltage of the output signal.

6. A shift register comprising:
a plurality of stages connected to one another in a row to perform a shift operation of an output signal by shifting input data using a plurality of clocks with different phases and outputting a clock input to a drain of an output transistor as a phase shift clock from a source upon the input data being input to a gate, wherein
the driver circuit according to claim 1 is used for the output transistor.

7. The shift register according to claim 6, wherein an (n−1)-th phase shift clock is input as shift data to an n-th stage to increase a gate voltage of the output transistor by a capacitor disposed between the source and the gate by using an n-th phase shift clock output from the source of the transistor.

8. A liquid crystal driver circuit including:
the shift register according to claim 7 to generate a scan driving signal for an active matrix circuit composed of scanning lines and signal lines intersecting with one another.
